(19) United States
(12) Patent Application Publication
(10) Pub. No.: US 2020/0089066 A1
(43) Pub. Date: Mar. 19, 2020

(54) ARRAY SUBSTRATE, DISPLAY PANEL, AND DISPLAY DEVICE

(71) Applicants: Chongqing HKC Optoelectronics Technology Co., Ltd., Chongqing (CN); HKC Corporation Limited, Shenzhen (CN)

(72) Inventor: Zeyao Li, Chongqing (CN)

(21) Appl. No.: 16/254,571

(22) Filed: Jan. 22, 2019

Related U.S. Application Data
(63) Continuation of application No. PCT/CN2018/111831, filed on Oct. 25, 2018.

(30) Foreign Application Priority Data
Sep. 17, 2018 (CN) 201821520443.3

(51) Int. Cl. G02F 1/1362; G02F 1/1368; G02F 1/1343; H01L 27/12

(52) U.S. Cl. CPC G02F 1/136286; G02F 1/1368; H01L 27/124; G02F 1/1343; G02F 1/136277

(57) ABSTRACT

The preset disclosure provides an array substrate, a display panel and a display device. The array substrate includes a substrate, a plurality of gate lines, a plurality of data lines, and a plurality of pixel structures, each of the pixel structures includes a thin film transistor and a pixel electrode both located at a side of the gate line, the pixel electrode electrically connects to the thin film transistor.

### CROSS REFERENCE TO RELATED APPLICATIONS

The present application is a Continuation Application of PCT Application No. PCT/CN2018/111831 filed on Oct. 25, 2018, which claims the benefit of Chinese Patent Application No. 201821520443.3, filed on Sep. 17, 2018, which is incorporated herein by reference in its entirety.

### FIELD

The present disclosure generally relates to the technical field of display, and more particularly relates to an array substrate, a display panel and a display device applied the array substrate.

### BACKGROUND

Liquid crystal display panel of the liquid crystal display includes a plurality of pixels, and each pixel includes three pixel units respectively representing three primary colors of red, green, and blue (RGB). Please refer to FIG. 1, which is a diagram of a pixel unit of a general liquid crystal display panel. The structure of the pixel unit includes a data line, a gate line, a thin film transistor (TFT), and a pixel electrode. Due to their own characteristics, the gate line and the data line are defined at a light-shielding region, and the pixel electrode is defined at a light-transmitting region. In order to transmit signals on the data line to the pixel electrode, the thin film transistor is connected to the data line and the pixel electrode respectively. Currently, the connection of the thin film transistor and the pixel electrode has affected the aperture ratio of the pixel structure, causing that the display effect of the display panel is not good.

### SUMMARY

It is therefore one main object of this disclosure to provide an array substrate, which aims to increase the aperture ratio of the pixel structure and improve the display effect.

In order to achieve the above aim, the array substrate provided by the present disclosure includes:

a substrate;

a plurality of gate lines and a plurality of data lines, all covering the substrate, the gate lines and data lines cross with each other to form a plurality of pixel regions;

a plurality of pixel structures, each of the pixel structures includes a thin film transistor covered on a gate line and a pixel electrode defined in one of the pixel regions; and

the pixel electrode and the thin film transistor are both located at a same side of the gate line, and the pixel electrode electrically connects to the thin film transistor.

In an exemplary embodiment of the present disclosure, the thin film transistor includes a gate electrode electrically connected to a gate line, a semiconductor layer located above the gate line, a first electrode and a second electrode both covering the semiconductor layer and spaced from each other, the second electrode electrically connects to the data line, and the pixel electrode electrically connects to the first electrode.

In an exemplary embodiment of the present disclosure, the array substrate further includes a first isolation layer and a second isolation layer, the first isolation layer is defined between the gate electrode and the semiconductor layer, the second isolation layer covers the first electrode and the second electrode, and the pixel electrode covers the second isolation layer and electrically connects with the first electrode.

In an exemplary embodiment of the present disclosure, the second isolation layer defines a connection port, and the pixel electrode defines a connection branch, which extends from an edge of the pixel electrode to the connection port, and the connection branch passes through the connection port to abut the first electrode.

In an exemplary embodiment of the present disclosure, the connection branch covers a periphery of the connection port, and extends around from the periphery of the connection port.

In an exemplary embodiment of the present disclosure, an area of the connection branch contacted with the first electrode has a range of 10 square microns to 80 square microns.

In an exemplary embodiment of the present disclosure, the pixel electrode includes common electrodes crosswise arranged, and a plurality of domains formed by divisions of the common electrodes, and each domain includes a plurality of pixel branches arranged in parallel and spaced from each other, and an angle is defined between the gate line and the pixel branch, or between the data line and the pixel branch.

In an exemplary embodiment of the present disclosure, the common electrodes cross with each other to form a cross shape, a plurality of pixel branches are radially arranged with the intersection of the common electrodes as a center, and a slit is formed between two adjacent pixel branches.

The present disclosure further provides a display panel, which includes the array substrate described as above, a color substrate, and the color substrate and the array substrate cooperatively forms a sealed space, the liquid crystal layer is defined in the sealed space.

The present disclosure further provides a display device, which includes the display panel described as above, and a backlight module connected to the display panel.

In the technical proposal of the present disclosure, the data lines and the gate lines on the array substrate divides the array substrate into a plurality of pixel regions, each of the pixel units defines the thin film transistor, as such each pixel structure can be controlled separately, and as the thin film transistor is defined on the gate line, such the thin film transistor does not affect the penetration of light, and the pixel electrode connects to the thin film transistor, the pixel electrode and the thin film transistor are both located at the same side of the gate line, the pixel electrode connects with the thin film transistor to occupy less area of the light-transmitting region, thus the aperture ratio of the pixel structure is increased, the penetration rate of the light is increased, and the display effect and the display quality are also effectively improved.

### BRIEF DESCRIPTION OF THE DRAWINGS

To better illustrate the technical solutions that are reflected in various embodiments according to this disclosure or that are found in the prior art, the accompanying drawings intended for the description of the embodiments herein or for the prior art will now be briefly described, it is evident that the accompanying drawings listed in the following description show merely some embodiments according to this disclosure, and that those having ordinary skill in the art will be able to obtain other drawings based on the arrangements shown in these drawings without making inventive efforts.

FIG. 1 is a structure diagram of the pixel unit of the array substrate according to an exemplary embodiment;

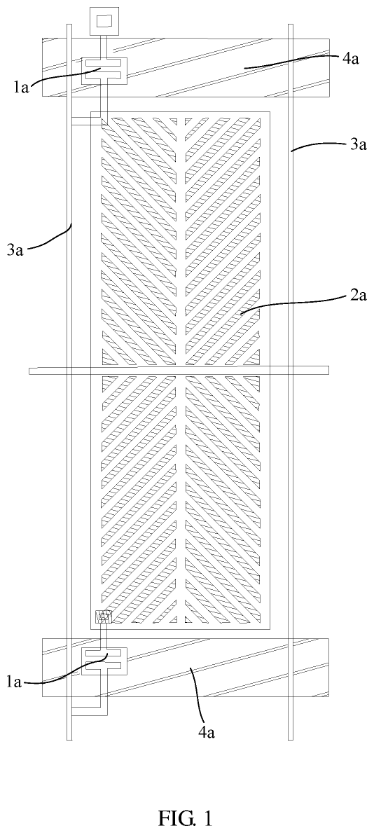

FIG. 2 is a structure diagram of a part of the pixel unit of the array substrate of the present disclosure according to an exemplary embodiment;

FIG. 3 is a cross section of the array substrate along line A-A shown in FIG. 2;

FIG. 4 is a structure diagram of a part of the pixel unit of the array substrate of the present disclosure according to another exemplary embodiment.

Labels illustration for drawings:

| Label | Name |
|---|---|
| 1a | thin film transistor |
| 2a | pixel electrode |
| 3a | scan line |
| 4a | gate line |
| 100 | array substrate |
| 1 | substrate |
| 2 | gate line |
| 3 | data line |
| 4 | pixel structure |
| 41 | thin film transistor |
| 411 | gate electrode |
| 412 | semiconductor layer |
| 413 | first electrode |
| 414 | second electrode |
| 42 | pixel electrode |
| 421 | connection branch |
| 422 | common electrode |
| 423 | pixel branch |
| 424 | slit |
| 43 | first isolation layer |
| 44 | second isolation layer |
| 441 | connection port |

The realization of the aim, functional characteristics, advantages of the present disclosure are further described specifically with reference to the accompanying drawings and embodiments.

### DETAILED DESCRIPTION

The technical solutions of the embodiments of the present disclosure will be clearly and completely described in the following with reference to the accompanying drawings. It is obvious that the embodiments to be described are only a part rather than all of the embodiments of the present disclosure. All other embodiments obtained by persons skilled in the art based on the embodiments of the present invention without creative efforts shall fall within the protection scope of the present invention.

It is to be understood that, all of the directional instructions in the exemplary embodiments of the present disclosure (such as top, down, left, right, front, back) can only be used for explaining relative position relations, moving condition of the elements under a special form (referring to figures), and so on, if the special form changes, the directional instructions changes accordingly.

In the present disclosure, unless specified or limited otherwise, the terms “connected,” “fixed” and the like are used broadly, and may be, for example, fixed connections, detachable connections, or integral connections; may also be mechanical or electrical connections; may also be direct connections or indirect connections via intervening structures; may also be inner communications of two elements. Which can be understood by those skilled in the art according to specific situations.

In addition, the descriptions, such as the “first”, the “second” in the present disclosure, can only be used for describing the aim of description, and cannot be understood as indicating or suggesting relative importance or impliedly indicating the number of the indicated technical character. Therefore, the character indicated by the “first”, the “second” can express or impliedly include at least one character.

In addition, the technical proposal of each exemplary embodiment can be combined with each other, however the technical proposal must base on that the ordinary skill in that art can realize the technical proposal, when the combination of the technical proposals occurs contradiction or cannot realize, it should consider that the combination of the technical proposals does not existed, and is not contained in the protection scope required by the present disclosure.

The present disclosure provides an array substrate 100.

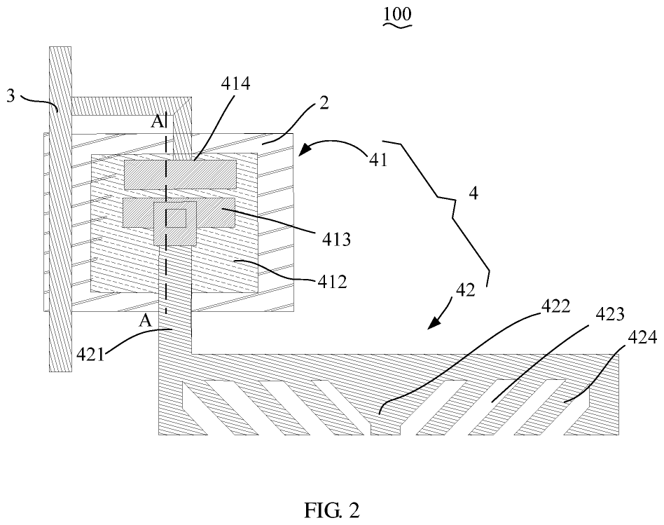

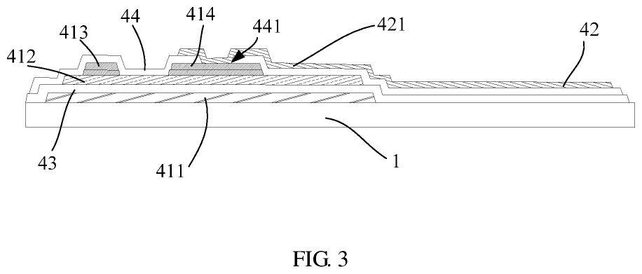

Referring to FIGS. 2-3, in the exemplary embodiment of the present disclosure, the array substrate 100 includes:

a substrate 1;

a plurality of gate lines 2 and a plurality of data lines 3, all covering the substrate 1, the gate lines 2 and data lines 3 cross with each other to form a plurality of pixel regions;

a plurality of pixel structures 4, each of the pixel structures 4 includes a thin film transistor 41 covered on a gate line 2 and a pixel electrode 42 defined in one of the pixel regions; and

the pixel electrode 42 electrically connects to the thin film transistor 41 at a side of the gate line 2.

In the embodiment, the array substrate 100 is a thin film transistor substrate, that is, a TFT substrate. The TFT substrate includes a substrate 1 which is made of a transparent glass plate, which does not affect penetration of light source and provides a basic carrier, but the substrate 1 is non-conductive. Since the movement and arrangement of liquid crystal molecules need to be driven by electrons during display process, the liquid crystal carrier glass needs conductive parts to control the movement of the liquid crystal. Therefore, the data line 3, the gate line 2, the thin film transistor 41 and the pixel electrode 42 are sequentially added to the substrate 1, and the above-mentioned elements are laminated on the substrate 1 through coating, exposure, development and etching processes to ensure the stability of the structure. Both the data line 3 and the gate line 2 are made of opaque non-ferrous metal material. The data line 3 receives the data signal from the data driving circuit and conveys the content to be displayed. The gate line 2 writes the data signal into the pixel electrode 42 and supplies the voltage to turn on and turn off the thin film transistor 41. The pixel electrode 42 drives the liquid crystal molecules when the circuit is turned on, so that light passes through to display the required content.

When looking down at the array substrate 100, the data line 3 perpendicularly cross with the gate line 2 to form a plurality of pixel regions, each pixel unit is internally provided with a thin film transistor 41 and a pixel electrode 42, and the thin film transistor 41 is provided on the gate line 2, and the pixel electrode 42 is located in each pixel region. The array substrate 100 has a light-transmitting area, and a light-shielding area, light can pass through light-transmitting area. The data line 3 and the gate line 2 are both made of non-ferrous metal which is opaque, so the data line 3 and the gate line 2 are located in the light-shielding area, the thin film transistor 41 is also located in the light-shielding area, the pixel electrode 42 is made of transparent conductive metal indium tin oxide (ITO), which does not block the backlight, so the pixel electrode 42 is located in the light-transmitting area, and the pixel electrode 42 and the thin film transistor 41 are connected to each other on the gate line 2, thus the pixel electrode 42 and the thin film transistor 41 do not affect the transmission of light in the light-transmitting area.

In the technical proposal of the present disclosure, the array substrate 100 includes data lines 3 and the gate lines 2 all on the substrate 1, the data lines 3 and the gate lines 2 divides the array substrate 100 into a plurality of pixel regions, each of the pixel units internally defines the thin film transistor 41, as such each pixel structure 4 can be controlled separately, and as the thin film transistor 41 is defined on the gate line 2, such the thin film transistor 41 does not affect the penetration of light, and the pixel electrode 42 connects to the thin film transistor at one side of the gate line, the pixel electrode 42 connects with the thin film transistor 41 to occupy less area of the light-transmitting region, the aperture ratio of the pixel structure 4 is increased, the light penetration rate is increased, and the display effect and the display quality are also effectively improved.

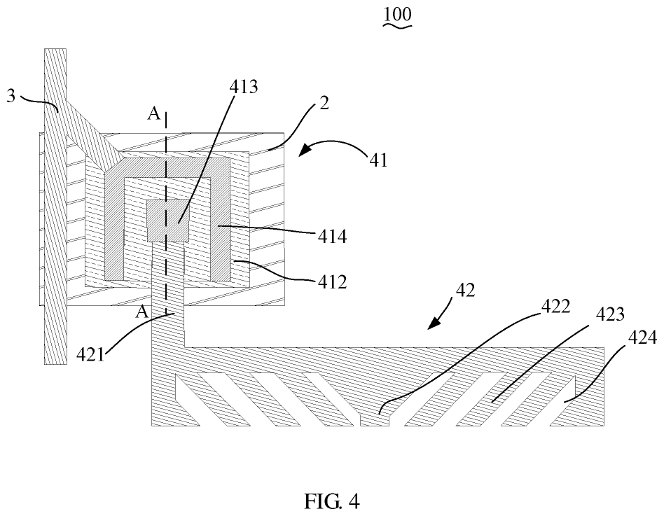

Referring to FIGS. 2-4, in detail, the thin film transistor 41 includes a gate electrode 411 electrically connected to a gate line 2, a semiconductor layer 412 located above the gate line 2, a first electrode 413 and a second electrode 414 both covering the semiconductor layer 412 and spaced from each other, the second electrode 414 electrically connects to the data line 3, and the pixel electrode 42 electrically connects to the first electrode 413.

In this embodiment, the thin film transistor 41 includes a gate electrode 411, a semiconductor layer 412, a first electrode 413 and a second electrode 414. The gate electrode 411, the first electrode 413 and the second electrode 414 are all metal layers that can conduct electricity, and the semiconductor layer 412 does not conduct electricity when the gate electrode 411 is not provided with electricity. It will be understood that the shapes of the first electrode 413 and the second electrode 414 may or may not be the same, and the first electrode 413 and the second electrode 414 are communicated when the semiconductor layer 412 becomes conductive. In one embodiment, the first electrode 413 and the second electrode 414 may both be plate-shaped and arranged in parallel, such the first electrode 413 and the second electrode 414 are facilitate to connect with the pixel electrode 42 and the data line 3. Of course, in another embodiment, the shape of the first electrode 413 is square, the second electrode 414 is enclosed to form a U shape to half surround the first electrode 413.

Among them, the first electrode 413 is a drain electrode, the second electrode 414 is a source electrode, or it may be that the first electrode 413 is a source electrode and the second electrode 414 is a drain electrode, specifically, it is related to the current flow. For example, when the first electrode 413 is connected to the pixel electrode 42 and the second electrode 414 is connected to the data line 3, when the thin film transistor 41 is charged, current flows from the second electrode 414 to the first electrode 413, the second electrode 414 is the source electrode and the first electrode 413 is the drain electrode. When the thin film transistor 41 discharges, current flows from the first electrode 413 to the second electrode 414, where the first electrode 413 is the source electrode and the second electrode 414 is the drain electrode.

The thin film transistor 41 is charged, and the second electrode 414 is electrically connected to the data line 3, and the first electrode 413 is connected to the pixel electrode 42. The gate electrode 411 is electrically connected with the gate line 2, and the gate electrode 411 and the gate line 2 cooperate with the semiconductor layer 412 to control the opening and closing of each pixel structure 4. Specifically, by charging to the gate electrode 411, the semiconductor layer 412 is made to be conductive, and then the first electrode 413 and the second electrode 414 are made to communicate with each other, so that the data of the data line 3 is transferred to the pixel electrode 42.

In addition, the array substrate 100 also includes a first isolation layer 43 and a second isolation layer 44, the first isolation layer 43 is disposed between the gate electrode 411 and the semiconductor layer 412, the second isolation layer 44 covers the first electrode 413 and the second electrode 414, and the pixel electrode 42 covers the second isolation layer 44 and electrically connects to the first electrode 413.

In the embodiment, the first isolation layer 43 and the second isolation layer 44 may be made of a non-conductive resin material, so as to prevent interference between adjacent conductive elements, thereby improving the display effect of the array substrate 100 without affecting the transmission of light. Since the second isolation layer 44 is arranged between the pixel electrode 42 and the first electrode 413, a window is required for the connection between the pixel electrode 42 and the first electrode 413, the window doe not let the light to pass through, so that the connection position of the pixel electrode 42 and the first electrode 413 is provided above the gate line 2, thereby the opaque area would not be increased, and the aperture ratio of the pixel structure 4 is increased.

Specifically, the second isolation layer 44 is provided with a connection port 441, and the pixel electrode 42 is provided with a connection branch 421 which extends from the edge of the pixel electrode 42 to the connection port 441, and the connection branch 421 passes through the connecting port 441 to abut the first electrode 413.

In the embodiment, the pixel electrode 42 can be connected with the first electrode 413 through the connection port 441, and the connection port 441 is located above the gate line 2, so that the connection position between the pixel electrode 42 and the first electrode 413 is set on the light shielding area, thereby increasing the light transmission area, the aperture ratio of the pixel structure 4 is increased, the light transmission rate is effectively increased, the number of liquid crystal molecules which are able to be imaged is increased, the light transmission rate is increased, and the display quality and brightness are improved to increase the display effect.

In an exemplary embodiment of the present disclosure, the connection branch 421 covers the periphery of the connection port 441 and extends around from the periphery of the connection port 441.

In this embodiment, the connection branch 421 covers the periphery of the connection port 441, that is, the portion of the connection branch 421 located at the connection port 441 matches with the connection port 441 in shape, so that the contact area between the connection branch 421 and the first electrode 413 can be increased, and the contact performance and the stability of power supply can be improved. And the connection branch 421 extends a certain distance around the periphery of the connection port 441, so that the cooperation between the connection branch 421 and the connection port 441 can be more stable, and the gap between the connection branch 421 and the connection port 441 due to assembly can be avoided, thereby ensuring the stability of the connection structure of the first electrode 413.

Specifically, the middle part of the connection branch 421 may be recessed into the connection port 441 to form a connection portion that coincides with the connection port 441, thereby improving the conductivity of the internal current between the connection branch 421 and the pixel electrode 42, thereby the charging rate is indirectly increased.

In an exemplary embodiment of the present disclosure, an area of the connection branch 421 contacted with the first electrode 413 has a range of 10 square microns to 80 square microns.

In the embodiment, according to the current technology, the size of the thin film transistor 41 has reached a relatively compact structure size. In order to realize the stable connection between the connection branch 421 and the first electrode 413 without increasing the size of the thin film transistor 41, the contact area between the connection branch 421 and the first electrode 413 is set to be 10 square microns to 80 square microns, thus significantly increasing the rate of energization, and avoiding insufficient driving force after power failure, the display stability of the display panel is ensured, and the display effect of the array substrate 100 is further improved.

Please refer to FIG. 2, in one embodiment of the present disclosure, the pixel electrode 42 has a plurality of common electrodes 422 crossed with each other, and a plurality of domains formed by the division of the common electrodes 422. Each domain is provided with a plurality of pixel branches 423, which are arranged in parallel and spaced from each other, and an angle is defined between the pixel branch 42 and the gate line 2, or between the pixel branch 42 and the data line 3.

In embodiment, the common electrode 422 of the pixel electrode 42 constitutes its main component, and is made of the same material as the pixel branch 423. The plurality of pixel branches 423 are arranged in parallel and spaced from each other, the plurality of pixel branches 423 extends from the periphery of the common electrode 422, that is, the pixel electrode 42 has an integral structure and is substantially fishbone shaped, thus improving the conduction stability of the pixel electrode 42.

Specifically, the common electrodes 422 cross with each other to for a cross shape, a plurality of pixel branches 423 are radially distributed with the intersection of the common electrodes 422 as a center, and a cut 424 is formed between two adjacent pixel branches 423.

In this embodiment, the two common electrodes 422 is cross-shaped, and one of the common electrodes 422 is parallel to the data line 3, and the other one is parallel to the gate line 2. The cross-shaped common electrode 422 can be divided into four regions, i.e., four domains, each domain is provided with a plurality of pixel branches 423, in each pixel branch 423 is radially distributed around the intersection of the common electrodes 422 which is defined as the center. In addition, the plurality of pixel branches 423 are arranged at 45 degrees to the periphery of the common electrode 422 in the four domains respectively, thereby increasing the rotating direction of liquid crystal molecule, as such a higher light transmittance is achieved.

The cut 424 (also called slit) are formed between the two adjacent pixel branches 423, so there are a plurality of cuts 424 which are also space from each other and arranged in parallel, and an angle is defined between the gate line 2 and the cut 424, or between the data line 3 and the cut 424, in detail, the angle is 45 degrees. The electrodes in the cuts 424 are densely arranged. Under the action of the electric field, the cuts 424 can drive the liquid crystal molecules to rotate in their inclination direction, so that the liquid crystal molecules can be inclined at 45 degrees. At this time, the maximum light transmittance can be achieved, and a high aperture ratio can be matched to achieve a high quality display effect.

The present disclosure also provides a display panel (not shown) which includes the foregoing array substrate 100, the color substrate (not shown) and the liquid crystal layer (not shown) as described above, the color substrate and the array substrate 100 cooperatively forms a sealed space, and the liquid crystal layer is disposed in the sealed space. The specific structure of the array substrate 100 refers to the above embodiments. Since the display panel adopts all the technical solutions of all the above embodiments, the display panel has at least all the effects of the technical solutions of the above embodiments, and will not be described in detail here.

In embodiment, the display panel may be a liquid crystal display panel. It can be understood that the display panel includes an array substrate 100 and a color filter (CF) facing the array substrate 100, and a liquid crystal layer sandwiched between the array substrate 100 and the color substrate. The array substrate 100 and the color substrate form a sealed space through a sealing frame, and the liquid crystal layer is located in the sealed space. The liquid crystal layer of the present disclosure may only have liquid crystal molecules or may include liquid crystal molecules and phototactic monomers.

The color substrate consists of a glass substrate, a shading layer, a color layer, a protective film and a conductive film. In TFT LCD, the glass substrate should be an alkali-free glass. The shading layer is an anti-reflection black matrix formed on the glass substrate to prevent light leakage between pixels and increase color contrast. Currently, the shading layer is usually made of metal film which is easy to make. The black matrix corresponds to the light shielding region of the array substrate 100. The color layer mainly uses the color photoresist as the filter film layer, and its components include high transparency and high heat resistance polymer resin binder, and dye colorant or pigment colorant, so that the transparent polymer resin has color and generally needs to have the characteristics of light resistance, good heat resistance, high color saturation and good penetrability, etc. The purpose of the protective film is to protect the color filter layer and increase the smoothness of the surface. The conductive film is a common electrode and is configured to form a potential difference with the pixel electrode 42 of the array substrate 100, to drive liquid crystal molecules.

The display panel is also provided with a lower polarizer defined at the lower surface of the array substrate 100 and an upper polarizer defined at the upper surface of the color substrate, the polarization direction of the lower polarizer is perpendicular to the polarization direction of the upper polarizer, and light passes through the lower polarizer first to become linearly polarized light, the polarization direction of linearly polarized light is consistent with the direction of the lower polarizer, and when linearly polarized light passing through the liquid crystal layer, due to refraction of liquid crystal molecules, the polarization direction of the light is twisted by 90 degrees with the help of the rotating angle of the liquid crystal molecules, thereby the light passing through the upper polarizer perpendicular to the lower polarizer to display images.

In order to further increase the rotating rate of liquid crystal molecules, the array substrate 100 may also be provided with an alignment film which covers the pixel electrode 42.

The alignment film is made of high molecular plastic. When making the alignment film, the solution-like material is coated on the surface of the array substrate 100 and then solidified. The roller made of flannel material rolls on the surface to make the surface present a certain friction alignment layer surface, which can generate a friction with liquid crystal molecules, thus making the liquid crystal molecules to present a certain pretilt angle. Under the action of the electric field, the liquid crystal molecules can be rotate more quickly and the light can penetrate quickly to ensure the accurate and rapid change of the image.

Of course, the color substrate is also provided with the alignment film, which can also make the liquid crystal molecules close to the color substrate to form a certain pretilt angle, thus further accelerating the rotating speed of the liquid crystal molecules under the action of the electric field, as such each of the pixels quickly display corresponding color.

When no voltage is applied to the display panel, the liquid crystal molecules located between the array substrate 100 and the color substrate are freely distributed, and the liquid crystal molecules closer to the alignment film may present a certain pretilt angle. When a voltage is applied to the display panel, the liquid crystal molecules are driven to rotate at the same angle by the plurality of slits 424 of the pixel electrode 42, thereby making the liquid crystal molecules to rotate more quickly, and ensuring the smooth penetration of light to realize a rapid imaging. When the voltage is removed, most of the liquid crystal molecules turn to an upright state, and light will not pass through at this time.

The present disclosure also provides a display device (not shown), the display device includes the foregoing display panel and a backlight module (not shown) connected to the display panel, the display panel includes the array substrate 100 in the above exemplary embodiments. As the display device adopts all the technical proposals of the above exemplary embodiments, the display device at least has all of the beneficial effects of the technical proposals of the above exemplary embodiments, no need to repeat again.

In embodiment, the backlight module is arranged close to the lower polarizer, and the backlight module is mainly arranged to provide a uniform light source with good brightness for the display device. The backlight module generally includes a light source, a light guide sheet, a reflection sheet and an optical film, and the reflection sheet may be a reflection coating coated on the surface of the light guide plate. The light guide sheet can convert the light source from a point light source to a uniform surface light source, and the arrangement of the reflection sheet can prevent light incident on the light guide plate from being emitted from the side away from the exit surface, and can reflect the light back into the light guide plate for preventing the waste of light energy and effectively improving the utilization rate of light. The backlight provided by the backlight module can enable the display device to obtain a better display effect.

The foregoing description merely depicts some embodiments of the present application and therefore is not intended to limit the scope of the application. An equivalent structural or flow changes made by using the content of the specification and drawings of the present application, or any direct or indirect applications of the disclosure on any other related fields shall all fall in the scope of the application.

What is claimed is:

1. An array substrate, wherein, the array substrate comprises:
a substrate;
a plurality of gate lines and a plurality of data lines, all covering the substrate, the gate lines and data lines cross with each other to form a plurality of pixel regions;
a plurality of pixel structures, each of the pixel structures comprises a thin film transistor covered on a gate line and a pixel electrode defined in one of the pixel regions; and
the pixel electrode electrically connects to the thin film transistor at a side of the gate line.

2. The array substrate according to claim 1, wherein, the thin film transistor comprises a gate electrode electrically connected to a gate line, a semiconductor layer located above the gate line, a first electrode and a second electrode both covering the semiconductor layer and spaced from each other, the second electrode electrically connects to the data line, and the pixel electrode electrically connects to the first electrode.

3. The array substrate according to claim 2, wherein, the array substrate further comprises a first isolation layer and a second isolation layer, the first isolation layer is defined between the gate electrode and the semiconductor layer, the second isolation layer covers the first electrode and the second electrode, and the pixel electrode covers the second isolation layer and electrically connects with the first electrode.

4. The array substrate according to claim 3, wherein, the second isolation layer defines a connection port, and the pixel electrode defines a connection branch which extends from an edge of the pixel electrode to the connection port, and the connection branch passes through the connection port to abut the first electrode.

5. The array substrate according to claim 4, wherein, the connection branch covers a periphery of the connection port, and extends around from the periphery of the connection port.

6. The array substrate according to claim 5, wherein, the middle part of the connection branch concavely defines a connection portion towards the connection port, the connection portion matches with the connection port.

7. The array substrate according to claim 5, wherein, an area of the connection branch contacted with the first electrode has a range of 10 square microns to 80 square microns.

8. The array substrate according to claim 5, wherein, the middle part of the connection branch concavely defines a connection portion towards the connection port, the connection portion matches with the connection port;
an area of the connection branch contacted with the first electrode has a range of 10 square microns to 80 square microns.

9. The array substrate according to claim 2, wherein, the first electrode and the second electrode are both plate-shaped, and arranged in parallel.

10. The array substrate according to claim 2, wherein, the array substrate further comprises a first isolation layer and a second isolation layer, the first isolation layer is defined between the gate electrode and the semiconductor layer, the second isolation layer covers the first electrode and the second electrode, and the pixel electrode covers the second isolation layer and electrically connects with the first electrode.

11. The array substrate according to claim 2, wherein, the first electrode is in a block shape; the second electrode is U shaped, and the second electrode half surrounds the first electrode.

12. The array substrate according to claim 1, wherein, the pixel electrode comprises common electrodes crosswise arranged, and a plurality of domains formed by divisions of the common electrodes, and each domain comprises a plurality of pixel branches arranged in parallel and spaced from each other, and an angle is defined between the gate line and the pixel branch, or between the data line and the pixel branch.

13. The array substrate according to claim 12, wherein, the pixel electrode has an integrated structure.

14. The array substrate according to claim 1, wherein, the pixel electrode comprises common electrodes crosswise arranged, and a plurality of domains formed by divisions of the common electrodes, and each domain comprises a plurality of pixel branches arranged in parallel and spaced from each other, and an angle defined between the gate line and the pixel branch, or between the data line and the pixel branch is 45 degrees.

15. The array substrate according to claim 14, wherein, the common electrodes cross with each other to form a cross shape, a plurality of pixel branches are radially arranged with the intersection of the common electrodes as a center, and a slit is formed between two adjacent pixel branches.

16. A display panel, wherein, the display panel comprises an array substrate, a color substrate, and a liquid crystal layer, the color substrate and the array substrate cooperatively forms a sealed space, the liquid crystal layer is defined in the sealed space, and the array substrate comprises:
a substrate;
a plurality of gate lines and a plurality of data lines, all covering the substrate, the gate lines and data lines cross with each other to form a plurality of pixel regions;
a plurality of pixel structures, each of the pixel structures comprises a thin film transistor covered on a gate line and a pixel electrode defined in one of the pixel regions; and
the pixel electrode electrically connects to the thin film transistor at a side of the gate line.

17. The display panel according to claim 16, wherein the thin film transistor comprises a gate electrode electrically connected to a gate line, a semiconductor layer located above the gate line, a first electrode and a second electrode both covering the semiconductor layer and spaced from each other, the second electrode electrically connects to the data line, and the pixel electrode electrically connects to the first electrode.

18. The display panel according to claim 16, wherein the array substrate further comprises an alignment film, the alignment film covers the pixel electrode.

19. The display panel according to claim 16, further comprising a lower polarizer and an upper polarizer, the lower polarizer is defined at a lower surface of the array substrate, the upper polarizer is defined at an upper surface of the color substrate.

20. A display device, wherein, the display device comprises a display panel and a backlight module connected to the display panel, the display panel comprises an array substrate, a color substrate, and the color substrate and the array substrate cooperatively forms a sealed space, the liquid crystal layer is defined in the sealed space, the array substrate comprises:
a substrate;
a plurality of gate lines and a plurality of data lines, all covering the substrate, the gate lines and data lines cross with each other to form a plurality of pixel regions;
a plurality of pixel structures, each of the pixel structures comprises a thin film transistor covered on a gate line and a pixel electrode defined in one of the pixel regions; and
the pixel electrode electrically connects to the thin film transistor at a side of the gate line.
